(19) United States
(12) Patent Application Publication
(10) Pub. No.: US 2023/0284481 A1
(43) Pub. Date: Sep. 7, 2023

(54) DISPLAY MODULE

(71) Applicant: Samsung Display Co., Ltd., Yongin-si (KR)

(72) Inventors: TAEHO KIM, Yongin-si (KR); HYEOJI KANG, Seoul (KR); OHJEONG KWON, Hwaseong-si, (KR); SU JEONG KIM, Seoul (KR); MIHWA LEE, Seoul (KR); HONGYEON LEE, Suwon-si (KR); SUNGGYU JANG, Asan-si (KR); SEUNGYEON JEONG, Hwaseong-si (KR)

(73) Assignee: Samsung Display Co., Ltd., Yongin-si (KR)

(21) Appl. No.: 18/104,841

(22) Filed: Feb. 2, 2023

(30) Foreign Application Priority Data
Mar. 4, 2022 (KR) 10-2022-0028401

(51) Int. Cl. H10K 59/122; H10K 59/80; H10K 50/15; H10K 50/16; H10K 50/17

(52) U.S. Cl. CPC H10K 59/122; H10K 59/873; H10K 50/15; H10K 50/16; H10K 50/171

(57) ABSTRACT

A display module is divided into a light-emitting region and a non-light-emitting region. The display module includes a base layer, a display element layer, an encapsulation substrate on the display element layer, and a light control layer including a colorant. The display element layer includes a pixel defining film having an opening defined therein to correspond to the light-emitting region, light-emitting elements adjacent to the pixel defining film, a first electrode exposed by the opening, a hole transport region on the first electrode to correspond to the light-emitting region and on the pixel defining film in the non-light-emitting region, a light-emitting layer on the hole transport layer to correspond to the light-emitting region, an electron transport layer on the light-emitting layer to correspond to the light-emitting region and on the hole transport layer in the non-light-emitting region, and a film formation suppression layer in the non-light-emitting region.

### CROSS-REFERENCE TO RELATED APPLICATION(S)

This application claims priority to and benefits of Korean Patent Application No. 10-2022-0028401 under 35 U.S.C. § 119, filed on Mar. 4, 2022, in the Korean Intellectual Property Office (KIPO), the entire contents of which are incorporated hereby by reference.

### BACKGROUND

### 1. Technical Field

Embodiments relate to a display module including a film formation suppression layer disposed in a non-light-emitting region.

### 2. Description of the Relate Art

Various electronic devices used in a multimedia device such as a television, a mobile phone, a tablet computer, and a game console, have been developed. An electronic device may include various optical functional layers to provide a high-quality color image to a user.

Recently, studies on a thin electronic device are being conducted to develop various types of electronic devices such as an electronic device having a curved surface, a rollable electronic device, or a foldable electronic device. For example, the thin electronic device has been implemented by reducing the number of optical functional layers and by equipping an optical functional layer having various functions.

In a display module, a reflection phenomenon caused by external natural light occurs, and this reflection phenomenon reduces the visibility of a display module. Studies are being conducted on a panel structure capable of reducing the reflection phenomenon caused by external natural light in order to improve the visibility of a display module.

### SUMMARY

Embodiments provide a display module capable of improving visibility by including a film formation suppression layer disposed in a non-light-emitting region.

In an embodiment, a display module divided into a light-emitting region and a non-light-emitting region may include: a base layer; a display element layer disposed on the base layer and including a pixel defining film including an opening disposed to correspond to the light-emitting region, and light-emitting elements adjacent to the pixel defining film; an encapsulation substrate disposed on the display element layer; and a light control layer disposed on the encapsulation substrate and including a colorant, wherein the display element layer may include a first electrode exposed by the opening, a hole transport layer disposed on the first electrode to correspond to the light-emitting region and disposed on the pixel defining film in the non-light-emitting region, a light-emitting layer disposed on the hole transport layer to correspond to the light-emitting region, an electron transport layer disposed on the light-emitting layer to correspond to the light-emitting region and disposed on the hole transport layer in the non-light-emitting region, a film formation suppression layer disposed on the electron transport layer in the non-light-emitting region, an electron injection layer disposed on the electron transport layer to correspond to the light-emitting region, a second electrode disposed on the electron injection layer, a capping layer disposed on the second electrode, and an inorganic deposition layer disposed on the capping layer.

In an embodiment, the electron injection layer, the second electrode, and the inorganic deposition layer may be formed in the opening by a patterning process.

In an embodiment, in a portion disposed in the non-light-emitting region, the film formation suppression layer may be an uppermost layer of the display element layer.

In an embodiment, the film formation suppression layer may be an organic layer.

In an embodiment, the film formation suppression layer may include at least one of pentafluorophenyl acrylate, 2,2,2-trifluoroethyl acrylate, 1H,1H,2H,2H-heptadecafluorodecyl methacrylate (HDFDMA), hexafluoro-iso-propyl methacrylate, 2,2,2-trifluoroethyl methacrylate, 1H,1H,5H-octafluoropentyl methacrylate, polytetrafluoroethylene (PTFE), polyethylene tetrafluoroethylene (ETFE), fluorinated-ethylene-propylene (FEP), perfluoro-alkoxy (PFA), 1H,1H,2H,2H-perfluorooctyltriethoxysilane, trichloro(1H,1H,2H,2H-perfluorooctyl)silane, hexadecafluoroheptane, perfluorooctane, or perfluorononane.

In an embodiment, the capping layer may be formed in the opening by a patterning process.

In an embodiment, an empty space may be between the inorganic deposition layer and the encapsulation substrate.

In an embodiment, the film formation suppression layer may include a first sub film formation suppression layer, and a second sub film formation suppression layer disposed on the first sub film formation suppression layer, the film formation suppression layer may further include a film formation capping layer disposed between the first sub film formation suppression layer and the second sub film formation suppression layer, and the capping layer and the film formation capping layer may be formed as a single layer throughout the light-emitting region and the non-light-emitting region.

In an embodiment, the display element layer may further include a filling layer disposed between the inorganic deposition layer and the encapsulation substrate to correspond to the light-emitting region and disposed between the film formation suppression layer and the encapsulation substrate in the non-light-emitting region.

In an embodiment, the inorganic deposition layer may include at least one of Al, Ag, Mg, Cr, Ti, Ni, Au, Ta, Cu, Ca, Co, Fe, Mo, W, Pt, Yb, SiO₂, TiO₂, ZrO₂, Ta₂O₅, HfO₂, Al₂O₃, ZnO, Y₂O₃, BeO, MgO, PbO₂, WO₃, SiNₓ, LiF, CaF₂, MgF₂, or CdS.

In an embodiment, the light control layer may not include a polarization layer and a color filter layer.

In an embodiment, a display module divided into a light-emitting region and a non-light-emitting region may include: a base layer; a display element layer disposed on the base layer and including a pixel defining film which has an opening defined therein to correspond to the light-emitting region; an encapsulation substrate disposed on the display element layer; and a light control layer disposed on the encapsulation substrate and including at least one of a pigment or a dye, wherein the display element layer may include a first portion including a first electrode, a hole transport layer, a light-emitting layer, an electron transport layer, an electron injection layer, a second electrode, a capping layer, and an inorganic deposition layer which are sequentially stacked on the base layer to correspond to the light-emitting region, and a second portion including the hole transport layer, the electron transport layer, and a film formation suppression layer which are sequentially stacked on the pixel defining film in the non-light-emitting region.

In an embodiment, the electron injection layer, the second electrode, and the inorganic deposition layer may be formed in the opening by a patterning process.

In an embodiment, wherein the film formation suppression layer may be an organic layer including a fluorine atom.

In an embodiment, the film formation suppression layer may include at least one of pentafluorophenyl acrylate, 2,2,2-trifluoroethyl acrylate, 1H,1H,2H,2H-heptadecafluorodecyl methacrylate (HDFDMA), hexafluoro-iso-propyl methacrylate, 2,2,2-trifluoroethyl methacrylate, 1H,1H,5H-octafluoropentyl methacrylate, polytetrafluoroethylene (PTFE), polyethylene tetrafluoroethylene (ETFE), fluorinated-ethylene-propylene (FEP), perfluoro-alkoxy (PFA), 1H,1H,2H,2H-perfluorooctyltriethoxysilane, trichloro(1H,1H,2H,2H-perfluorooctyl)silane, hexadecafluoroheptane, perfluorooctane, or perfluorononane.

In an embodiment, the capping layer may be formed in the opening by a patterning process.

In an embodiment, an empty space may be between the inorganic deposition layer and the encapsulation substrate.

In an embodiment, the display module may further include a filling layer disposed between the display element layer and the encapsulation substrate.

In an embodiment, the film formation suppression layer may include a first sub film formation suppression layer, and a second sub film formation suppression layer disposed on the first sub film formation suppression layer, the second portion may further include a film formation capping layer disposed between the first sub film formation suppression layer and the second sub film formation suppression layer, and the capping layer and the film formation capping layer are formed as a single layer throughout the light-emitting region and the non-light-emitting region.

In an embodiment, the light control layer may not include a polarization layer and a color filter layer.

### BRIEF DESCRIPTION OF THE FIGURES

The accompanying drawings are included to provide a further understanding of the invention, and are incorporated in and constitute a part of this specification. The drawings illustrate the embodiments and, together with the description, serve to explain principles of the invention. In the drawings:

FIG. 1 is a schematic perspective view of an electronic device according to an embodiment;

FIG. 2 is a schematic exploded perspective view of an electronic device according to an embodiment;

FIG. 3 is a schematic plan view of a display module according to an embodiment;

FIG. 4 is a schematic cross-sectional view of a display module according to an embodiment;

FIG. 5 is a schematic cross-sectional view of a display module according to an embodiment;

FIG. 6 is a schematic cross-sectional view of a display module according to an embodiment;

FIG. 7 shows a transmittance versus a wavelength length in display modules according to Examples and Comparative Examples; and

FIG. 8 shows an SCI reflectance versus a wavelength length in display modules according to Examples and Comparative Examples

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

It will be understood that when an element (or a region, a layer, a portion, or the like) is referred to as being “on”, “connected to” or “coupled to” another element, it may be directly disposed on, connected or coupled to another element mentioned above, or intervening elements may be disposed therebetween. Further, “directly disposed” means that there is no additional layer, film, region, plate, or the like added between the portion of the layer, film, region. For example, “directly disposed” may mean disposing without additional members such as adhesive members between two layers or two members.

Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Like numbers refer to like elements throughout. Also, in the drawings, the thicknesses, ratios, and dimensions of the elements are exaggerated for effective description of the technical contents.

The term “and/or” includes all of one or more combinations which may be defined by related components.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

Also, terms such as “below”, “lower”, “above”, and “upper” may be used to describe the relationships of the components illustrated in the drawings. These terms have relative concepts and are described on the basis of the directions indicated in the drawings. In the specification, being “disposed on” may represent not only being disposed on the upper portion but also being disposed on the lower portion.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, numbers, steps, operations, elements, components, or a combination thereof, but does not preclude the presence or addition of one or more other features, numbers, steps, operations, elements, components, or combinations thereof.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, an electronic device according to an embodiment will be described with reference to the drawings.

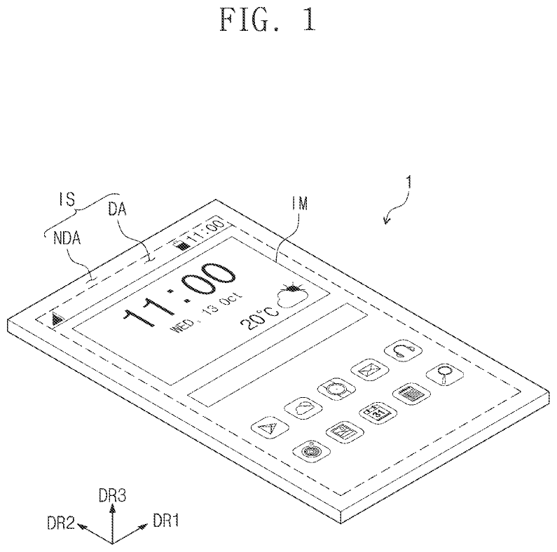

FIG. 1 is a schematic perspective view of an electronic device according to an embodiment. FIG. 1 illustrates a portable electronic apparatus as an electronic device 1. However, the electronic device 1 may be used in not only a large-sized electronic device such as a television, a monitor, or an external billboard, but also a small-sized electronic device or a medium-sized electronic device such as a personal computer, a notebook computer, a personal digital terminal, a car navigation unit, a game machine, a smartphone, a tablet, and a camera. However, these are presented only as examples, so that the electronic device may also be used in other electronic apparatuses.

The electronic device 1 may have a hexahedral shape having a thickness in a third direction DR3 on a plane defined by a first direction DR1 and a second direction DR2 which cross each other. However, this is illustrated by way of example, and the electronic device 1 may have various shapes, and embodiments are not limited thereto.

In an embodiment, an upper surface (or a front surface) and a lower surface (or a rear surface) of each member are defined based on a direction in which an image IM is displayed. The upper and lower surfaces of each member may be opposed to each other in the direction of the third direction DR3, and a normal line direction of each of the upper and lower surfaces may be parallel to the direction of the third direction DR3.

The directions indicated by the first, second, and third direction DR1, DR2, and DR3 may have a relative concept and may thus be changed to other directions. Hereinafter, first, second, and third directions are the directions respectively indicated by the first and third direction DR1, DR2, and DR3 and are thus denoted as the same reference numerals or symbols.

The electronic device 1 may display an image IM through a display surface IS. The display surface IS may include a display region DA on which an image IM is displayed and a non-display region NDA adjacent to the display region DA. The non-display region NDA may be a region in which the image is not displayed. The image IM may include static images or dynamic images. In FIG. 1, application icons, a clock, and the like are illustrated as an example of the image IM.

The display region DA may have a quadrilateral shape. The non-display region NDA may surround the display region DA. However, embodiments are not limited thereto, and the shape of the display region DA and the shape of the non-display region NDA may be variously designed. For example, the non-display region NDA may be omitted on a front surface of the electronic device 1.

The electronic device 1 may be flexible. The electronic device 1 may have bendable properties, and the electronic device 1 may include all structures from a fully folded structure to a structure bendable to a level of several nanometers. For example, the electronic device 1 may be a curved electronic device or a foldable electronic device. However, embodiments are not limited thereto, and the electronic device 1 may be rigid.

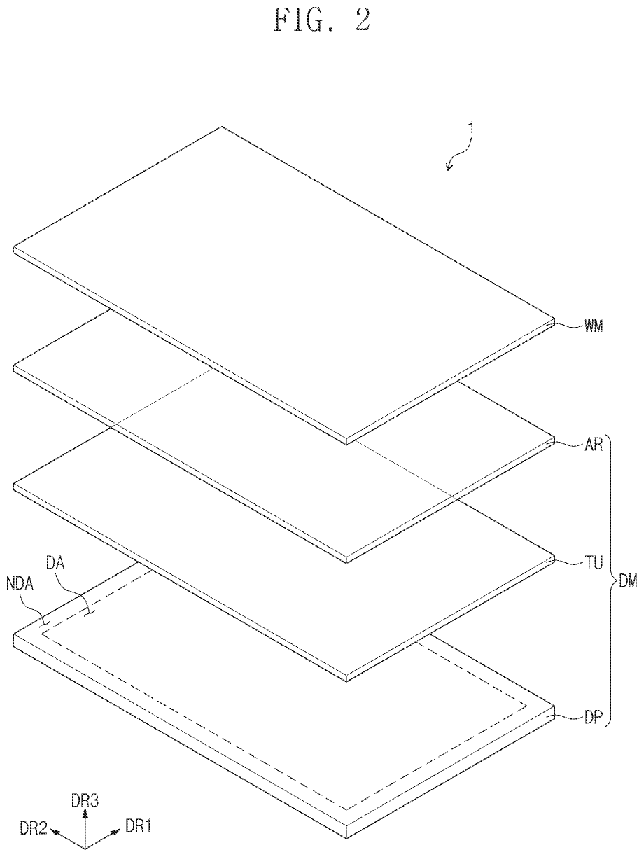

FIG. 2 is a schematic exploded perspective view of an electronic device according to an embodiment. Referring to FIG. 2, the electronic device 1 may include a display module DM, and a window WM that are sequentially stacked along the third direction DR3. The display module DM may include a display panel DP and a light control layer AR disposed on the display panel DP. The display module DM may further include a sensor layer TU disposed between the display panel DP and the light control layer AR. The sensor layer TU may sense a touch input. For example, the sensor layer TU may include a sensor base layer BS-TU, a sensor insulating layer IL, sensor electrodes SP1 and SP2, a contact hole CN, and a cover layer OL. For example, the sensor electrodes SP1 and SP2 may be connected to each other through the contact hole CN passing through the sensor insulating layer IL. The sensor insulating layer IL may be disposed on the sensor base layer BS-TU, and the cover layer OL may be disposed on the sensor insulating layer IL.

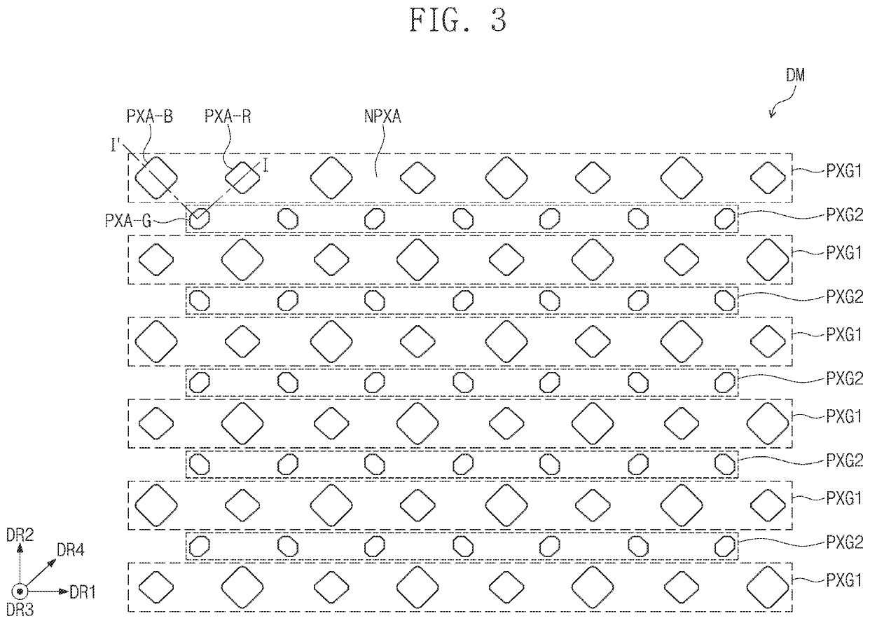

The display panel DP may include pixels in the display region DA. The pixels may correspond to (or be disposed in) the light-emitting regions PXA-R, PXA-B, and PXA-G (see FIG. 3). The pixels may display light in response to an electrical signal. Due to the pixels, the display region DA may display the image IM (see FIG. 1) generated by the light.

The display panel DP may be a self-luminous display panel. For example, the display panel DP may be a micro LED display panel, a nano LED display panel, an organic light-emitting display panel, or a quantum dot light-emitting display panel. However, this is merely an example, and the display panel DP is not limited thereto as long as being a self-luminous display panel.

A light-emitting layer of the organic light-emitting display panel may include an organic light-emitting material. A light-emitting layer of the quantum-dot light-emitting display panel may include quantum dots and/or quantum rods. The micro LED display panel may include a micro light-emitting diode element, which is an ultra-small light-emitting element, and the nano LED display panel may include a nano light-emitting diode element. Hereinafter, the display panel DP is described as an organic light-emitting display panel.

The light control layer AR may be disposed on the display panel DP. The light control layer AR may be disposed on the uppermost part of the display module DM. The light control layer AR may be an anti-reflection layer that reduces reflectance with respect to external light incident from the outside. The light control layer AR may be a layer that selectively transmits light emitted from the display panel DP.

The light control layer AR may not include a polarization layer. Accordingly, light passing through the light control layer AR and incident onto the display panel DP and the sensor layer TU may be unpolarized light. For example, the light control layer AR may not include a color filter layer.

The sensor layer TU may be disposed between the display panel DP and the light control layer AR. The sensor layer TU may sense the external input, and may acquire information for generating an image on the display panel DP according to the external input. The external input may be a user's input. The user's input may include various types of external inputs such as a portion of the user's body, light, heat, a pen, or pressure.

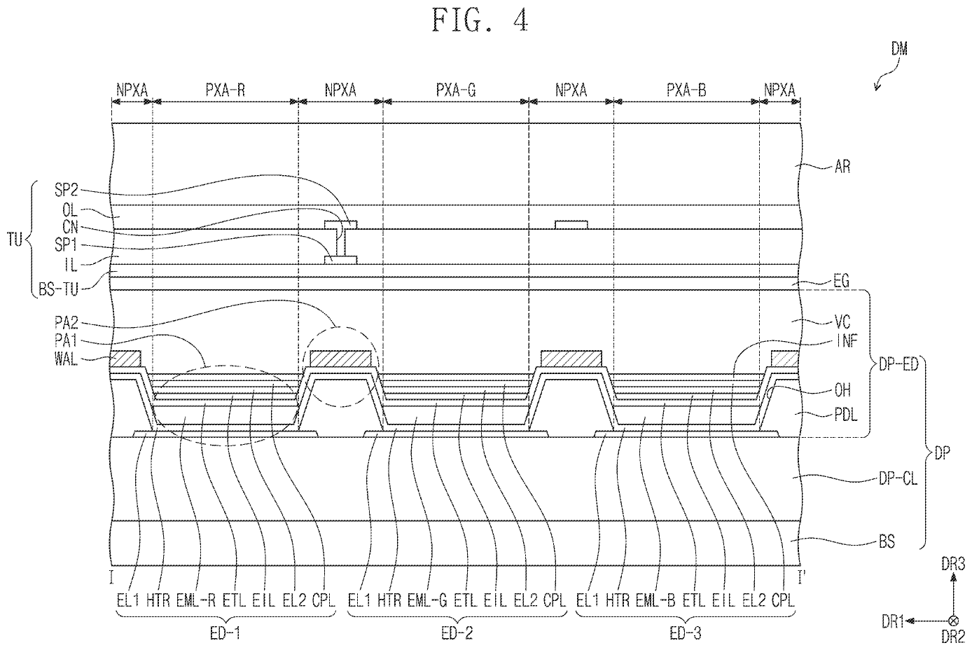

FIG. 3 is a schematic plan view of a display module according to an embodiment. FIG. 4 is a schematic cross-sectional view of a display module according to an embodiment. FIG. 4 is a schematic cross-sectional view taken along line I-I′ of FIG. 3 in a display module according to an embodiment.

Referring to FIGS. 3 and 4, the display module DM according to an embodiment may include a non-light-emitting region NPXA and light-emitting regions PXA-R, PXA-G, and PXA-B. The light-emitting regions PXA-R, PXA-G, and PXA-B may be regions in which light generated by the respective light-emitting elements ED-1, ED-2, and ED-3 is emitted. The areas (or sizes) of the light-emitting regions PXA-R, PXA-B, and PXA-G may be different from each other, and the areas (or sizes) may be measured when viewed in a plan view.

The light-emitting regions PXA-B, PXA-G, and PXA-R may be classified into pixel groups PXG1 and PXG2 according to the color of light generated from the light-emitting elements ED-1, ED-2, and ED-3. For example, the pixel group PXG1 may include the light-emitting regions PXA-R and PXA-B that are alternately arranged in the first direction DR1, and the pixel group PXG2 may include the light-emitting regions PXA-G that are arranged in the first direction DR1. In the display module DM according to an embodiment illustrated in FIGS. 3 and 4, three light-emitting regions PXA-R, PXA-G, and PXA-B may respectively emit red light, green light, and blue light.

The light-emitting regions PXA-R, PXA-G, and PXA-B may have different areas (or sizes) according to colors emitted from the light-emitting layers EML-R, EML-G, and EML-B of the light-emitting elements ED-1, ED-2, and ED-3. For example, referring to FIG. 3, in the display module DM according to an embodiment, a blue light-emitting region PXA-B of the light-emitting element ED-2, which emits blue light, may have the largest area on a plane, and a green light-emitting region PXA-G of the light-emitting element, which generates green light, may have the smallest area in a plan view. However, this is merely an example, and embodiments are not limited thereto.

In another example, the light-emitting regions PXA-R, PXA-G, and PXA-B may emit light of colors other than red light, green light, and blue light, the light-emitting regions PXA-R, PXA-G, and PXA-B may have the same area (or same size), or the light-emitting regions PXA-R, PXA-G, and PXA-B may have an area ratio different from that illustrated in FIG. 3.

Each of the light-emitting regions PXA-R, PXA-G, and PXA-B may be a region divided by a pixel defining film PDL. The non-light-emitting region NPXA may be located between the adjacent light-emitting regions PXA-B, PXA-G, and PXA-R and may correspond to (or overlap) the pixel defining film PDL. In this specification, each of the light-emitting regions PXA-R, PXA-G, and PXA-B may correspond to (or form) a pixel.

The arrangement structure of the light-emitting regions PXA-R, PXA-G, and PXA-B illustrated in FIG. 3 may be referred to as Pentile™ structure. However, the arrangement structure of the light-emitting regions PXA-R, PXA-G, and PXA-B in the display module according to an embodiment is not limited to the arrangement structure illustrated in FIG. 3.

For example, in an embodiment, the light-emitting regions PXA-R, PXA-G, and PXA-B may also have a stripe structure in which the red light-emitting regions PXA-R, the green light-emitting regions PXA-G, and the blue light-emitting regions PXA-B are alternately arranged in order along the first direction DR1.

The display panel DP may include abase layer BS, a circuit layer DP-CL, and a display element layer DP-ED that are sequentially stacked. The display element layer DP-ED may include the pixel defining films PDL, the light-emitting elements ED-1, ED-2, and ED-3 disposed between the pixel defining films PDL, and the inorganic deposition layers INF disposed on the light-emitting elements ED-1, ED-2, and ED-3.

For example, the display element layer DP-ED may include a first portion PA1 and a second portion PA2. The first portion PA1 may be a portion corresponding to (or disposed in) the light-emitting regions PXA-R, PXA-G, and PXA-B. The second portion PA2 may be a portion corresponding to (or disposed in) the non-light-emitting region NPXA. The first portion PA1 may include a first electrode EL1, a hole transport region HTR, light-emitting layers EML-R, EML-G, and EML-B, an electron transport layer ETL, an electron injection layer EIL, a second electrode EL2, a capping layer CPL, and an inorganic deposition layer INF that are sequentially stacked on the base layer BS. The second portion PA2 may include the hole transport region HTR, the electron transport layer ETL, and a film formation suppression layer WAL that are sequentially stacked on the pixel defining film PDL.

The base layer BS may be a member that provides a base surface on which a circuit layer DP-CL is disposed. The base layer BS may be a glass substrate, a metal substrate, a polymer substrate, or the like. However, embodiments are not limited thereto, and the base layer BS may be an inorganic layer, an organic layer, or a composite material layer.

In an embodiment, the circuit layer DP-CL may be disposed on the base layer BS, and the circuit layer DP-CL may include transistors. Each of the transistors may include a control electrode, an input electrode, and an output electrode. For example, the circuit layer DP-CL may include a switching transistor and a driving transistor for driving the light-emitting elements ED-1, ED-2, and ED-3 of the display element layer DP-ED.

The pixel defining film PDL may be formed of a polymer resin. For example, the pixel defining film PDL may include the polyacrylate-based resin or the polyimide-based resin. For example, the pixel defining film PDL may further include an inorganic material in addition to the polymer resin. The pixel defining film PDL may include a light absorbing material or may be formed including a black pigment or black dye. The pixel defining film PDL including the black pigment or black dye may form a black pixel defining film. Carbon black or the like may be used as the black pigment or black dye in case that the pixel defining film PDL is formed, but embodiments are not limited thereto.

For example, the pixel defining film PDL may be formed of an inorganic material. For example, the pixel defining film PDL may include nitride (SiNₓ), silicon oxide (SiOX), or silicon oxynitride (SiOxNy). The pixel defining film PDL may define the light-emitting regions PXA-R, PXA-G, and PXA-B. The light-emitting regions PXA-R, PXA-G, and PXA-B and the non-light-emitting region NPXA may be divided by the pixel defining film PDL.

Each of the light-emitting elements ED-1, ED-2, and ED-3 may include the first electrode EL1, the hole transport region HTR, the light-emitting layer EML-R, EML-G, or EML-B, the electron transport layer ETL, the electron injection layer EIL, the second electrode EL2, and the capping layer CPL.

The first electrode EL1 may be disposed on the circuit layer DP-CL. The first electrode EL1 may be formed in the light-emitting regions PXA-R, PXA-G, and PXA-B through a patterning process. The first electrode EL1 may be exposed by the opening OH defined (or formed) in the pixel defining film PDL.

The hole transport region HTR may be disposed on the first electrode EL1 to correspond to the light-emitting regions PXA-R, PXA-G, and PXA-B, and may be disposed on the pixel defining films PDL to the correspond to the non-light-emitting region NPXA. The hole transport region HTR may be formed as a single layer in the light-emitting regions PXA-R, PXA-G, and PXA-B and the non-light-emitting region NPXA. However, this is merely an example, and embodiments are not limited thereto. The hole transport region HTR may be formed on the light-emitting regions PXA-R, PXA-G, and PXA-B through a patterning process.

The light-emitting layers EML-R, EML-G, and EML-B may be disposed on the hole transport region HTR to correspond to the light-emitting regions PXA-R, PXA-G, and PXA-B, respectively. The light-emitting layers EML-R, EML-G, and EML-B may be formed in the light-emitting regions PXA-R, PXA-G, and PXA-B through a patterning process. The light-emitting layers EML-R, EML-G, and EML-B may be disposed in the opening OH defined (or formed) in the pixel defining film PDL.

The electron transport layer ETL may be disposed on the light-emitting layers EML-R, EML-G, and EML-B to respectively correspond to (or to respectively overlap) the light-emitting regions PXA-R, PXA-G, and PXA-B and may be disposed on the hole transport region HTR to correspond to the non-light-emitting region NPXA. The electron transport layer ETL may be formed as a single layer in the light-emitting regions PXA-R, PXA-G, and PXA-B and the non-light-emitting region NPXA. However, this is merely an example, and embodiments are not limited thereto, and the electron transport layer ETL may be formed on the light-emitting regions PXA-R, PXA-G, and PXA-B through a patterning process.

The film formation suppression layer WAL may be disposed on the electron transport layer ETL to correspond to the non-light-emitting region NPXA. The film formation suppression layer WAL may be an uppermost layer of the display element layer DP-ED in the non-light-emitting region NPXA. The film formation suppression layer WAL may prevent the electron injection layer EIL, the second electrode EL2, and the inorganic deposition layer INF from being formed in the non-light-emitting region NPXA.

The film formation suppression layer WAL may be an inorganic layer, an organic layer, or an organic-inorganic composite material layer. In case that the film formation suppression layer WAL is an organic layer or an organic-inorganic composite material layer, the film formation suppression layer WAL may include an organic compound including a fluorine atom as a substituent. For example, the film formation suppression layer WAL may be an organic compound including at least one of —CF, —CF₂, or CF₃.

For example, the film formation suppression layer WAL may include at least one of a fluorinated monomer, a fluorinated polymer, a fluorinated sliane compound, or a fluorinated alkyl compound. For example, the film formation suppression layer WAL may include at least one of pentafluorophenyl acrylate, 2,2,2-trifluoroethyl acrylate, 1H,1H,2H,2H-heptadecafluorodecyl methacrylate (HDFDMA), hexafluoro-iso-propyl methacrylate, 2,2,2-trifluoroethyl methacrylate, 1H,1H,5H-octafluoropentyl methacrylate, polytetrafluoroethylene (PTFE), polyethylene tetrafluoroethylene (ETFE), fluorinated-ethylene-propylene (FEP), perfluoro-alkoxy (PFA), 1H,1H,2H,2H-perfluorooctyltriethoxysilane, trichloro(1H,1H,2H,2H-perfluorooctyl)silane), hexadecafluoroheptane, perfluorooctane, or perfluorononane.

In an embodiment, the electron injection layer EIL may be disposed on the electron transport layer ETL in the light-emitting regions PXA-R, PXA-G, and PXA-B. The electron injection layer EIL may be formed in the light-emitting regions PXA-R, PXA-G, and PXA-B through a patterning process. The electron injection layer EIL may be disposed in the opening OH. The deposition of the electron injection layer EIL on the film formation suppression layer WAL may be prevented or limited. Accordingly, the electron injection layer EIL may not be disposed in a portion corresponding to (or disposed in) the non-light-emitting region NPXA.

In an embodiment, the second electrode EL2 may be disposed on the electron injection layer EIL. The second electrode EL2 may be disposed on the electron injection layer EIL to correspond to the light-emitting regions PXA-R, PXA-G, and PXA-B. The second electrode EL2 may be formed in the light-emitting regions PXA-R, PXA-G, and PXA-B through a patterning process. The second electrode EL2 may be disposed in the opening OH. The deposition of the second electrode EL2 on the film formation suppression layer WAL may be prevented or limited. Accordingly, in the display module DM according to an embodiment, the second electrode EL2 may not be disposed in a portion corresponding to (or disposed in) the non-light-emitting region NPXA.

In an embodiment, the capping layer CPL may be disposed on the second electrode EL2 to correspond to the light-emitting regions PXA-R, PXA-G, and PXA-B. The capping layer CPL may be formed in the light-emitting regions PXA-R, PXA-G, and PXA-B through a patterning process. The capping layer CPL may be disposed in the opening OH.

In an embodiment, the inorganic deposition layer INF may be disposed on the capping layer CPL to correspond to the light-emitting regions PXA-R, PXA-G, and PXA-B. The inorganic deposition layer INF may be disposed on (e.g., directly on) the capping layer CPL. The inorganic deposition layer INF may be formed in the light light-emitting regions PXA-R, PXA-G, and PXA-B through a patterning process. The inorganic deposition layer INF may be disposed in the opening OH. The deposition of the inorganic deposition layer INF on the film formation suppression layer WAL may be prevented or limited. Accordingly, in the display module DM according to an embodiment, the inorganic deposition layer INF may not be disposed in a portion corresponding to (or disposed in) the non-light-emitting region NPXA. As a result, the display module DM according to an embodiment may reduce, in the non-light-emitting region NPXA, the amount of light reflected from the inorganic deposition layer INF to the outside.

The inorganic deposition layer INF may be a layer for preventing external light from being reflected by the second electrode EL2 of each of the light-emitting elements ED-1, ED-2, and ED-3. For example, destructive interference may occur between the light reflected from the surface of the inorganic deposition layer INF and the light reflected from the second electrode EL2. Thus, the amount of light, which is reflected from the second electrode EL2 and emitted to the outside, may be reduced or minimized. The thickness of the inorganic deposition layer INF and the thickness of the capping layer CPL may be controlled or modified so that destructive interference may occur between the light reflected from the surface of the inorganic deposition layer INF and the light reflected from the second electrode EL2.

The inorganic deposition layer INF may include an inorganic material having a refractive index of about 1.0 or more and a light absorption coefficient of about 0.5 or more. The inorganic deposition layer INF may be formed by a thermal deposition process and may include an inorganic material having a melting point of about 1000° C. or less. For example, the inorganic deposition layer INF may include at least one of Al, Ag, Mg, Cr, Ti, Ni, Au, Ta, Cu, Ca, Co, Fe, Mo, W, Pt, Yb, SiO₂, TiO₂, ZrO₂, Ta₂O₅, HfO₂, Al₂O₃, ZnO, Y₂O, BeO, MgO, PbO₂, WO₃, SiNₓ, LiF, CaF₂, MgF₂, CdS, or a combination thereof. An encapsulation substrate EG may be disposed (e.g., directly disposed) on the inorganic deposition layer INF.

The encapsulation substrate EG may be disposed on the display element layer DP-ED. The encapsulation substrate EG may cover the light-emitting elements ED-1, ED-2, and ED-3. The encapsulation substrate EG may encapsulate the display element layer DP-ED. The encapsulation substrate EG may be a glass substrate, a metal substrate, or a plastic substrate. However, embodiments are not limited thereto, and the encapsulation substrate EG may be an inorganic layer, an organic layer, or a composite material layer. An empty space VC may be disposed between the inorganic deposition layer INF and the encapsulation substrate EG may be a vacuum space. However, embodiments are not limited thereto. For example, the empty space VC may include air or gas.

The light control layer AR may be disposed on the encapsulation substrate EG. The light control layer AR may be disposed on the display panel DP. The light control layer AR may overlap (e.g., entirely overlap) the display element layer DP-ED. The light control layer AR may overlap (e.g., entirely overlap) each of the first light-emitting element ED-1, the second light-emitting element ED-2, and the third light-emitting element ED-3. The light control layer AR may be disposed to correspond to all of the light-emitting regions PXA-R, PXA-G, and PXA-B and the non-light-emitting region NPXA. The light control layer AR may be formed as a single layer.

The light control layer AR may cover the front surface (or the upper surface) of the display panel DP to protect the display panel DP. Portion of light, which is emitted from the display panel DP and then passed through the light control layer AR, may be absorbed and another portion of the light may be transmitted to improve color gamut. The color gamut refers to a range of colors that an electronic device 1 is able to display. For example, the color gamut may be improved by selectively absorbing light in a specific wavelength range.

The light control layer AR may include at least one of a pigment or a dye. For example, the light control layer AR may include at least one selected from the group consisting of an anthraquinone-based compound, a phtalocyanine-based compound, an azo-based compound, a perylene-based compound, a xanthene-based compound, a diimmonium-based compound, a dipyrromethene-based compound, a tetraazaporphyrin-based compound, a porphyrin-based compound, a squarylium-based compound, an oxazine-based compound, a triarylmethane-based compound, a cyanine-based compound, and a combination thereof. For example, the light control layer AR may include any one among a tetraazaporphyrin-based compound, a cyanine-based compound, a squarylium-based compound, and an oxazine-based compound, and a combination thereof.

The display module DM according to an embodiment may not include a color filter layer for filtering light and a polarization layer for polarizing light. The display module DM according to an embodiment may include an inorganic deposition layer INF and a light control layer AR including a colorant CR and may replace the functions of the color filter layer and the polarization layer. For example, the light control layer AR may not include the color filter layer and the polarization layer. For example, the display module DM may include the inorganic deposition layer INF and the light control layer AR to adjust the color tone of the display module DM visually recognized by the user.

In another example, the light control layer AR of the display module DM may be disposed to correspond to the non-light-emitting region NPXA, and may not include partition wall portions that block external light. Accordingly, in the light control layer AR, the amount of transmittance of external light in each of the portion corresponding to (or disposed in) the light-emitting regions PXA-R, PXA-G, and PXA-B and the amount of transmittance of external light in the portion corresponding to the non-light-emitting region NPXA may be same as each other. External light passing through the light control layer AR and incident on the display panel DP may be reflected to the outside by the display panel DP, and the light reflected to the outside by the display panel DP may affect the color tone of the display module DM visually recognized by the user in case that power of the display panel DP is turned off.

For example, compared to the case where the light control layer AR includes the partition wall portions that block external light, the amount of light passing through the light control layer AR and incident on the display panel DP may increase in case that the light control layer AR does not include the partition wall portions that block external light like the display module DM according to an embodiment. Accordingly, the amount of light reflected to the outside by the display panel DP may increase, thereby adversely affecting the color tone of the display module DM visually recognized by the user.

In the display module DM according to an embodiment, the reflectance of a portion where the display panel DP corresponds to (or is disposed in) the non-light-emitting region NPXA may be lowered to adjust a color tone visually recognized by a user. For example, in the display module DM according to an embodiment, the film formation suppression layer WAL may be disposed on the uppermost layer of a portion where the display element layer DP-ED corresponds to (or is disposed in) the non-light-emitting region NPXA.

The film formation suppression layer WAL may restrict the formation of the electron injection layer EIL, the second electrode EL2, and the inorganic deposition layer INF in the portion where the display element layer DP-ED corresponds to (or is disposed in) the non-light-emitting region NPXA. Accordingly, in the display module DM according to an embodiment, the film formation suppression layer WAL may be disposed on the uppermost layer of the portion where the display element layer DP-ED corresponds to (or is disposed in) the non-light-emitting region NPXA.

The film formation suppression layer WAL may have a lower specular component included (SCI) reflectance than the inorganic deposition layer INF. For example, in the display module DM according to an embodiment, the film formation suppression layer WAL may be disposed on the uppermost layer of the portion where the display element layer DP-ED corresponds to (or is disposed in) the non-light-emitting region NPXA, and therefore display module DM may have a lower SCI reflectance compared to the case where the inorganic deposition layer INF is disposed on the uppermost layer of the portion where the display element layer DP-ED corresponds to (or is disposed in) the non-light-emitting region NPXA. Accordingly, the color tone of the display module DM visually recognized by the user according to an embodiment may be improved.

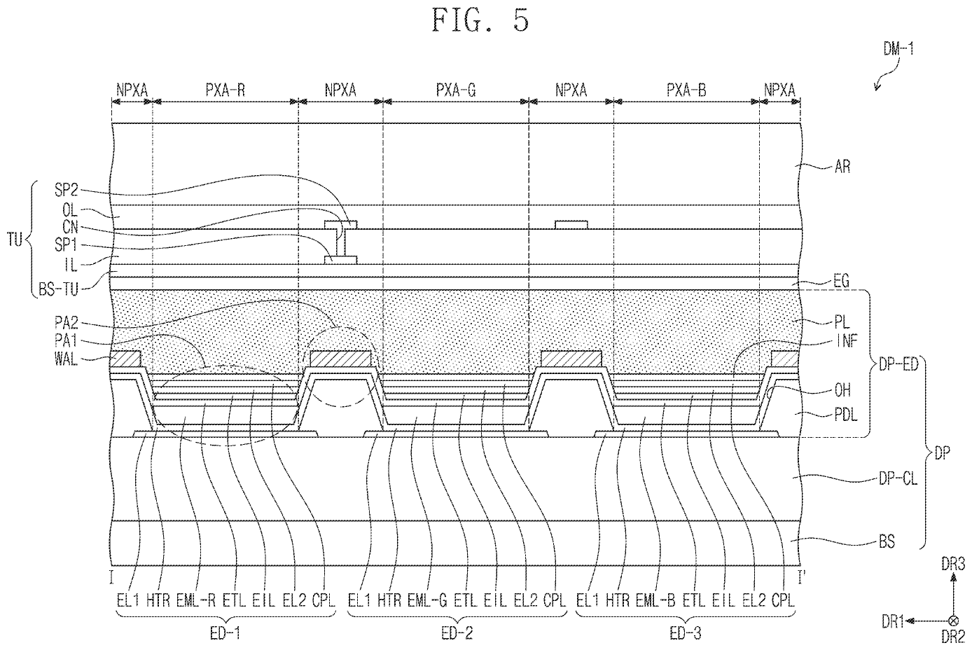

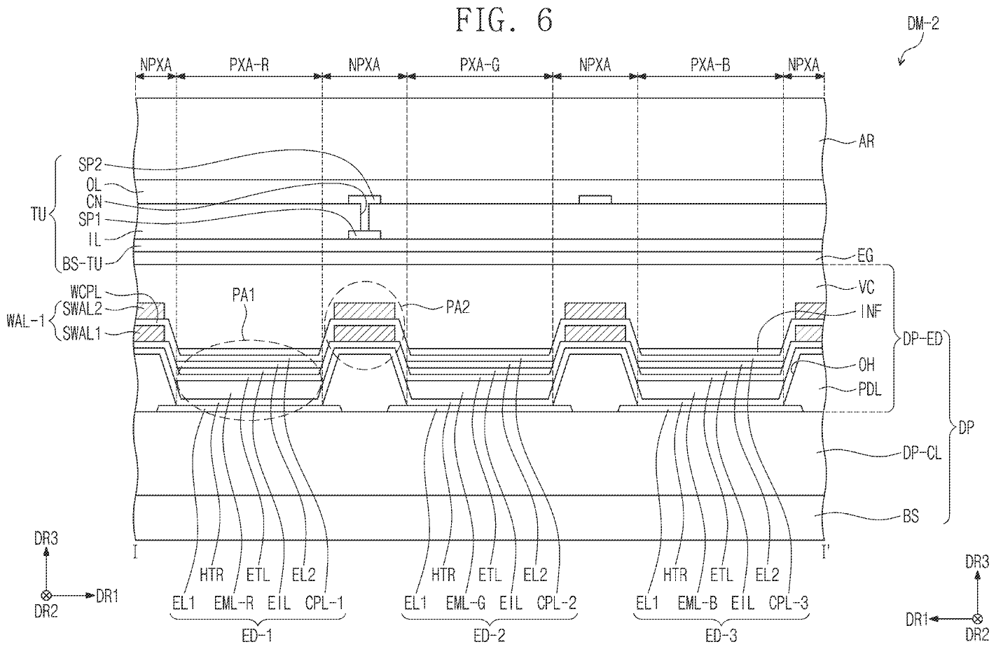

FIGS. 5 and 6 are schematic cross-sectional views of a display module according to an embodiment. Hereinafter, the display modules DM-1 and DM-2 according to an embodiment will be described in detail with reference to FIGS. 5 and 6. The redundant contents as those described with reference to FIGS. 1, 2, 3, and 4 will not be described again, but description will be focused on differences for descriptive convenience.

The display module DM-1 according to an embodiment illustrated in FIG. 5 is different from the display module DM (see FIG. 4) described with reference to FIGS. 1, 2, 3, and 4 in that the display module DM-1 further includes a filling layer PL disposed between the inorganic deposition layer INF and the encapsulation substrate EG.

Referring to FIG. 5, in the display module DM-1 according to an embodiment, the display element layer DP-ED may further include the filling layer PL. The filling layer PL may be disposed between the inorganic deposition layer INF and the encapsulation substrate EG to correspond to the light-emitting regions PXA-R, PXA-G, and PXA-B and may be disposed between the film formation suppression layer WAL and the encapsulation substrate EG to correspond to the non-light-emitting region. The filling layer PL may cover the film formation suppression layer WAL and the inorganic deposition layer INF. The filling layer PL may support the encapsulation substrate EG. The filling layer PL may include an organic material, an inorganic material, or an organic-inorganic composite material.

The display module DM-2 according to an embodiment illustrated in FIG. 6 is different from the display module DM (see FIG. 4) described with reference to FIGS. 1 to 4 in that a film formation suppression layer WAL-1 includes sub film formation suppression layers SWAL1 and SWAL2, and further includes a film formation capping layer WCPL.

In the display module DM-2 according to an embodiment, the film formation suppression layer WAL-1 may include a first sub film formation suppression layer SWAL1 and a second sub film formation suppression layer SWAL2. The first sub film formation suppression layer SWAL1 may be disposed more adjacent to (or closer to) the pixel defining film PDL than the second sub film formation suppression layer SWAL2. The second sub film formation suppression layer SWAL2 may be disposed on an uppermost layer of the non-light-emitting region NPXA of the display element layer DP-ED. In the display module DM-2 according to an embodiment, the second sub film formation suppression layer SWAL2 may be disposed on the uppermost layer of the non-light-emitting region NPXA of the display element layer DP-ED. Thus, the display module DM-2 according to an embodiment may have a low SCI reflectance with respect to external light, and thus the color tone visually recognized by the user may be improved.

The display module DM-2 according to an embodiment may further include a film formation capping layer WCPL between the first sub film formation suppression layer SWAL1 and the second sub film formation suppression layer SWAL2. The film formation capping layer WCPL may be disposed to correspond to the non-light-emitting region NPXA. The film formation capping layer WCPL may be formed as a single layer throughout capping layers CPL-1, CPL-2, and CPL-3, the light-emitting regions PXA-R, PXA-G, and PXA-B, and the non-light-emitting region NPXA. For example, the second portion PA2 may further include a film formation capping layer WCPL disposed between the first sub film formation suppression layer SWAL1 and the second sub film formation suppression layer SWAL2. The capping layers CPL-1, CPL-2, and CPL-3 included in the first portion PA1 and the film formation capping layer WCPL included in the second portion PA2 may be formed as a single layer throughout light-emitting regions PXA-R, PXA-G, and PXA-B and the non-light-emitting region NPXA.

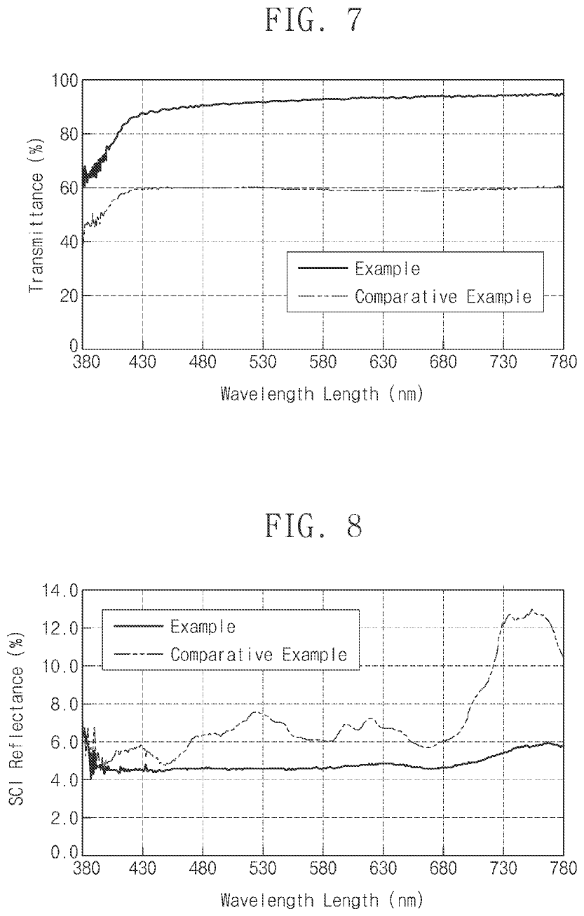

FIG. 7 shows a transmittance versus a wavelength length in display modules according to Examples and Comparative Examples. FIG. 8 shows an SCI reflectance versus a wavelength length in display modules according to Examples and Comparative Examples.

(Target to be Evaluated for Transmittance and SCI Reflectance)

The display module of Example may have substantially the same structure as that described with reference to FIG. 4. The display module of Comparative Example may have substantially the same structure as the display module of Example, except that, unlike the display module of Example, the display module of Comparative Example does not include a film formation suppression layer in a portion where the display element layer corresponds to (or is disposed in) the non-light-emitting region, but include an inorganic deposition layer disposed on the uppermost layer of the portion where the display element layer corresponds to (or is disposed in) the non-light-emitting region.

(Evaluation Method for Transmittance and SCI Reflectance)

The SCI reflectance and transmittance for light having a wavelength of about 380 nm to about 780 nm were measured using CM-3600D. The reflectance was measured at an angle of about 5 degrees.

(Evaluation Results of Transmittance and SCI Reflectance)

Referring to FIG. 7, the display module of Example may have a higher transmittance in the entire wavelength range than the display module of Comparative Example. Thus, the transmittance of the display module may be increased in case that the inorganic deposition layer is not disposed but the film formation suppression layer is disposed on the uppermost layer of the portion where the display panel corresponds to (or is disposed in) the non-light-emitting region.

Referring to FIG. 8, the display module of Example may have a lower SCI reflectance in the entire wavelength range than the display module of Comparative Example. Thus, the reflectance of the display module may be decreased in case that the inorganic deposition layer is not disposed but the film formation suppression layer is disposed on the uppermost layer of the portion where the display panel corresponds to (or is disposed in) the non-light-emitting region.

A display module according to an embodiment may include a film formation suppression layer that is disposed in a non-light-emitting region and prevents an inorganic deposition layer from being disposed in the non-light-emitting region, thereby providing a display module having a low reflectance with respect to external light, and thus having improved visibility.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display module divided into a light-emitting region and a non-light-emitting region, the display module comprising:
a base layer;
a display element layer disposed on the base layer, the display element layer including:
a pixel defining film which has an opening defined therein to correspond to the light-emitting region, and
light-emitting elements adjacent to the pixel defining film;
an encapsulation substrate disposed on the display element layer; and
a light control layer disposed on the encapsulation substrate, the light control layer including a colorant, wherein
the display element layer comprises:
a first electrode exposed by the opening,
a hole transport region disposed on the first electrode in the light-emitting region and disposed on the pixel defining film in the non-light-emitting region,
a light-emitting layer disposed on the hole transport region in the light-emitting region,
an electron transport layer disposed on the light-emitting layer in the light-emitting region and disposed on the hole transport region in the non-light-emitting region,
a film formation suppression layer disposed on the electron transport layer in the non-light-emitting region,
an electron injection layer disposed on the electron transport layer in the light-emitting region,
a second electrode disposed on the electron injection layer,
a capping layer disposed on the second electrode, and
an inorganic deposition layer disposed on the capping layer.

2. The display module of claim 1, wherein the electron injection layer, the second electrode, and the inorganic deposition layer are formed in the opening by a patterning process.

3. The display module of claim 1, wherein in a portion disposed in the non-light-emitting region, the film formation suppression layer is an uppermost layer of the display element layer.

4. The display module of claim 1, wherein the film formation suppression layer is an organic layer.

5. The display module of claim 4, wherein the film formation suppression layer comprises at least one of pentafluorophenyl acrylate, 2,2,2-trifluoroethyl acrylate, 1H,1H,2H,2H-heptadecafluorodecyl methacrylate (HDFDMA), hexafluoro-iso-propyl methacrylate, 2,2,2-trifluoroethyl methacrylate, 1H,1H,5H-octafluoropentyl methacrylate, polytetrafluoroethylene (PTFE), polyethylene tetrafluoroethylene (ETFE), fluorinated-ethylene-propylene (FEP), perfluoro-alkoxy (PFA), 1H,1H,2H,2H-perfluorooctyltriethoxysilane, trichloro(1H,1H,2H,2H-perfluorooctyl)silane, hexadecafluoroheptane, perfluorooctane, or perfluorononane.

6. The display module of claim 1, wherein the capping layer is formed in the opening by a patterning process.

7. The display module of claim 1, wherein an empty space is disposed between the inorganic deposition layer and the encapsulation substrate.

8. The display module of claim 1, wherein
the film formation suppression layer comprises:
a first sub film formation suppression layer, and
a second sub film formation suppression layer disposed on the first sub film formation suppression layer,
the film formation suppression layer further comprises a film formation capping layer disposed between the first sub film formation suppression layer and the second sub film formation suppression layer, and
the capping layer and the film formation capping layer are formed as a single layer throughout the light-emitting region and the non-light-emitting region.

9. The display module of claim 1, wherein the display element layer further comprises a filling layer disposed between the inorganic deposition layer and the encapsulation substrate in the light-emitting region and disposed between the film formation suppression layer and the encapsulation substrate in the non-light-emitting region

10. The display module of claim 1, wherein the inorganic deposition layer includes at least one of Al, Ag, Mg, Cr, Ti, Ni, Au, Ta, Cu, Ca, Co, Fe, Mo, W, Pt, Yb, SiO₂, TiO₂, ZrO₂, Ta₂O₅, HfO₂, Al₂O₃, ZnO, Y₂O₃, BeO, MgO, PbO₂, WO₃, SiNₓ, LiF, CaF₂, MgF₂, or CdS.

11. The display module of claim 1, wherein the light control layer does not comprise a polarization layer and a color filter layer.

12. A display module divided into a light-emitting region and a non-light-emitting region, the display module comprising:
a base layer;
a display element layer disposed on the base layer, the display element layer including a pixel defining film which has an opening defined therein to correspond to the light-emitting region;
an encapsulation substrate disposed on the display element layer; and
a light control layer disposed on the encapsulation substrate, the light control layer including at least one of a pigment or a dye, wherein
the display element layer comprises:
a first portion including a first electrode, a hole transport region, a light-emitting layer, an electron transport layer, an electron injection layer, a second electrode, a capping layer, and an inorganic deposition layer which are sequentially stacked on the base layer to correspond to the light-emitting region, and
a second portion including the hole transport region, the electron transport layer, and a film formation suppression layer which are sequentially stacked on the pixel defining film in the non-light-emitting region.

13. The display module of claim 12, wherein the electron injection layer, the second electrode, and the inorganic deposition layer are formed in the opening by a patterning process.

14. The display module of claim 12, wherein the film formation suppression layer is an organic layer including a fluorine atom.

15. The display module of claim 14, wherein the film formation suppression layer comprises at least one of pentafluorophenyl acrylate, 2,2,2-trifluoroethyl acrylate, 1H,1H,2H,2H-heptadecafluorodecyl methacrylate (HDFDMA), hexafluoro-iso-propyl methacrylate, 2,2,2-trifluoroethyl methacrylate, 1H,1H,5H-octafluoropentyl methacrylate, polytetrafluoroethylene (PTFE), polyethylene tetrafluoroethylene (ETFE), fluorinated-ethylene-propylene (FEP), perfluoro-alkoxy (PFA), 1H,1H,2H,2H-perfluorooctyltriethoxysilane, trichloro(1H,1H,2H,2H-perfluorooctyl)silane, hexadecafluoroheptane, perfluorooctane, or perfluorononane.

16. The display module of claim 12, wherein the capping layer is formed in the opening by a patterning process.

17. The display module of claim 12, wherein an empty space is disposed between the inorganic deposition layer and the encapsulation substrate.

18. The display module of claim 12, further comprising a filling layer disposed between the display element layer and the encapsulation substrate.

19. The display module of claim 12, wherein
the film formation suppression layer comprises:
a first sub film formation suppression layer, and
a second sub film formation suppression layer disposed on the first sub film formation suppression layer,
the second portion further includes a film formation capping layer disposed between the first sub film formation suppression layer and the second sub film formation suppression layer, and
the capping layer and the film formation capping layer are formed as a single layer throughout the light-emitting region and the non-light-emitting region.

20. The display module of claim 12, wherein the light control layer does not comprise a polarization layer and a color filter layer.
